(19) United States
(12) Patent Application Publication
(10) Pub. No.: US 2014/0262749 A1
(43) Pub. Date: Sep. 18, 2014

(54) Methods of Plasma Surface Treatment in a PVD Chamber

(71) Applicant: Intermolecular, Inc., San Jose, CA (US)

(72) Inventors: Ashish Bodke, San Jose, CA (US); Olov Karlsson, San Jose, CA (US); Kevin Kashefi, San Jose, CA (US); Chi-I Lang, Cupertino, CA (US); Dipankar Pramanik, Saratoga, CA (US); Hong Sheng Yang, Pleasanton, CA (US); Xuena Zhang, San Jose, CA (US)

(73) Assignee: INTERMOLECULAR, INC., San Jose, CA (US)

(21) Appl. No.: 13/804,265

(22) Filed: Mar. 14, 2013

(51) Int. Cl. C23C 14/35

(52) U.S. Cl. CPC C23C 14/35
USPC 204/192.12

(57) ABSTRACT

Combinatorial processing of a substrate comprising site-isolated sputter deposition and site-isolated plasma processing can be performed in a same process chamber. The process chamber, configured to perform sputter deposition and plasma processing, comprises a grounded shield having at least an aperture disposed above the substrate to form a small, dark space gap to reduce or eliminate any plasma formation within the gap. The plasma processing may include plasma etching or plasma surface treatment.

### TECHNICAL FIELD

The present disclosure relates generally to semiconductor manufacturing and in particular to radio frequency (RF) plasma treatment in a plasma deposition chamber with a biasable pedestal for full wafer and combinatorial processing.

### BACKGROUND

Plasma processing or manufacturing techniques are used in the manufacture of integrated circuits (IC) semiconductor devices, flat panel displays, optoelectronics devices, data storage devices, magneto electronic devices, magneto optic devices, packaged devices, and the like.

Deposition processes are commonly used in semiconductor manufacturing to deposit a layer of material onto a substrate. Physical vapor deposition (PVD) is one example of a deposition process, and sputter deposition or sputtering is a common physical vapor deposition method. In sputtering, ions or neutral species are ejected from a target material by high-energy particle bombardment and then deposited onto the substrate using plasma. In some process sequences, it may be desirable to expose the surface to a plasma pre-treatment step before or after the sputter deposition. For site isolated deposition (i.e., deposition on a site isolated region of the substrate), PVD tools typically include an aperture through which the sputtered ions are targeted. While PVD tools are commonly used in the industry, they are limited to performing specific processes and do not permit much flexibility.

As feature sizes continue to shrink on semiconductor devices, improvements, whether in materials, unit processes, or process sequences, are continually being sought in these semiconductor processes. In order to identify different materials, evaluate different unit process conditions or parameters, or evaluate different sequencing and integration of processes, and combinations thereof, it is desirable to process isolated regions of the substrate using different process conditions to improve the efficiency of research and development. This capability is called “combinatorial processing”, and it is generally not performed with tools that are designed specifically for conventional full substrate processing. It is also desirable to subject isolated regions of the substrate to different processing conditions (e.g., localized deposition) in one step of a sequence followed by subjecting the full substrate to a similar processing condition (e.g., full substrate deposition) in another step.

Further developments and improvements, particularly innovations that enable flexibility and increased throughput, and provide combinatorial processing, in semiconductor manufacturing are needed.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, the present invention discloses a biasable substrate support for full substrate and combinatorial processing. The biasable pedestal can be used in an electrostatic chuck (ESC), for example, for substrate precleaning or plasma treating.

In some embodiments, the biasable pedestal can be used in a physical vapor deposition (PVD) chamber, for example, a chamber with one or more sputter guns, enabling PVD sputter deposition, and etch, or plasma surface treatment, eliminating the need for a separate plasma chamber.

In some embodiments, a substrate shield having apertures is disposed on the substrate so that the bottoms of the apertures are flush with the bottom of lower shield so that a small, constant, dark-space gap is ensured between the grounded shield and the entire substrate (except the area exposed by the aperture holes). The width of the gap is preferably smaller than a width of the plasma sheath, for example, less than 3 mm. Using the substrate shield, a typical PVD chamber, (e.g., one with one or multiple sputter guns), can be used for Ar⁺ etch by applying RF power to the biasable pedestal and igniting plasma with Ar gas flow. Alternatively, oxygen or nitrogen gases can be used. The PVD chamber becomes a multi-purpose chamber, capable of sputter deposition, plasma etch, and plasma surface treatment. In some embodiments, the shield with the aperture is removed or the aperture size is increased so that the entire surface of the substrate may be exposed to the surface treatment.

In some embodiments, methods for combinatorial processing a substrate are described, characterized in that site-isolated sputter deposition and site-isolated plasma treatment are performed in the same process chamber. The method further comprises shielding the substrate surface while exposing at least one site-isolated region of the substrate, wherein the shield forms a small dark space gap with the substrate to reduce or eliminate any plasma formation within the gap.

In some embodiments, methods for combinatorial processing a substrate are described, comprising exposing a site-isolated region of the substrate, and plasma surface treating the site-isolated region before sputter depositing material on the site-isolated region.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 is a simplified schematic diagram illustrating an exemplary sputter processing chamber according to some embodiments.

FIGS. 5A and 5B illustrate a partial cross-sectional view showing the sputter and plasma processing chamber according to some embodiments.

FIGS. 6A and 6B illustrate a partial cross-sectional view showing the sputter and plasma processing chamber according to some embodiments.

FIG. 7 is an perspective view of the sputter and plasma processing chamber according to some embodiments.

FIG. 8 illustrates an exemplary flowchart for processing a substrate according to some embodiments.

FIG. 9 illustrates an exemplary flowchart for processing a substrate according to some embodiments.

FIG. 10 illustrates an exemplary flowchart for processing a substrate according to some embodiments.

FIG. 11 illustrates an exemplary flowchart for processing a substrate according to some embodiments.

FIG. 12 illustrates an exemplary flowchart for processing a substrate according to some embodiments.

### DETAILED DESCRIPTION

Some embodiments of the invention are directed to combined sputter deposition and plasma processes being performed in one process chamber. The chamber may include multiple sputter guns. An aperture and a grounded shield are placed above the substrate. The bottom of the aperture is flush with the bottom of the lower shield so that a small, constant dark-space gap is formed between the substrate and the aperture. A dielectric material may be used in the dark-space gap. The substrate is supported by a substrate support, such as an electrostatic chuck. A bias voltage can be applied to the substrate support, and plasma may be ignited with the one or more sputter guns while performing plasma processes (e.g. plasma etch or plasma surface treatment) in the chamber. The chamber is capable of performing both PVD sputter deposition and plasma processes, eliminating the need for a separate plasma chamber.

As used herein, the phrases “plasma processes” and “plasma processing” will be understood to mean one or more of plasma etch or plasma surface treatment. The phrase “plasma surface treatment” will be understood to encompass one or more of nitridation, oxidation, fluorination, chlorination, hydrogen treatment, and the like, and involves the exposure of the surface to a reactive species created by the use of a plasma.

The manufacture of semiconductor devices entails the integration and sequencing of many unit processing steps. As an example, semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as semiconductor devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, the entireties of which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005, the entireties of which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), and chemical vapor deposition (CVD).

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It will be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It will be appreciated that these process parameters are exemplary and not meant to be an exhaustive list as other process parameters commonly used in semiconductor manufacturing may be varied.

FIG. 3 is a simplified schematic diagram illustrating an integrated high productivity combinatorial (HPC) system in accordance with some embodiments of the invention. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. application Ser. Nos. 11/672,478 and 11/672,473, the entire disclosures of which are herein incorporated by reference. In a HPC system, a plurality of methods may be employed to deposit material upon a substrate employing combinatorial processes.

In some embodiments, a process chamber for combinatorial processing of a substrate is provided that includes one or more sputter targets (such as sputter guns); a power source coupled to the one or more sputter guns; a substrate support; a power source (e.g. RF, DC, pulsed, or the like) coupled to the substrate support; and a grounded shield comprising an aperture disposed between the substrate support and the one or more sputter guns to form a dark-space gap between the substrate support and the aperture. The aperture may be configured to allow sputter deposition or plasma processing of a site-isolated region on the substrate.

The process chamber may further include a plasma confinement ring between the substrate support and the grounded shield. The plasma confinement ring may be thicker than the substrate. The plasma confinement ring fills the dark-space gap between the substrate support and the grounded shield.

The process chamber may further include a dielectric material in the dark-space gap. The dielectric material may be coated with a metal layer for grounding and RF shielding. The dark-space gap may be between about 1 mm and about 3 mm.

The process chamber may further include a controller to selectively apply power to the one or more sputter guns from the power source and apply power to bias the substrate support from a power source. The controller may be configured to control the power source to perform one or both of plasma processing and PVD deposition on a site-isolated region on the substrate. In some embodiments, other sputter mechanisms can be used instead of the sputter guns.

In some embodiments, a semiconductor processing system for combinatorial processing of a substrate is provided that includes a process chamber having a dark-space region configured to prevent plasma leaks in a region adjacent the substrate. The process chamber can be configured to perform both plasma processing and sputter deposition on a site-isolated region on the substrate. The process chamber may include a dielectric material in the dark-space gap. The dark-space region may be between about 1 mm and about 3 mm.

The process chamber may include a plasma confinement ring positioned around the substrate to prevent plasma leak in a region adjacent the substrate. The plasma confinement ring may be thicker than the substrate. The plasma confinement ring may be a conductive material or ceramic material which may or may not be partially coated with a metal layer.

In some embodiments, a method of combinatorial processing of a substrate is provided in which site-isolated sputter deposition and plasma processing are performed in the same process chamber. The site-isolated sputter deposition may include site-isolated co-sputtering deposition. Cleaning, site-isolated sputter deposition, and plasma processing may be performed in the same process chamber. Cleaning, site-isolated sputter deposition and plasma processing, and full wafer sputter deposition may be performed in the same process chamber.

FIG. 4 is a simplified schematic diagram illustrating an exemplary process chamber 400 configured to perform combinatorial processing and full substrate processing in accordance with some embodiments of the invention. It will be appreciated that the processing chamber shown in FIG. 4 is merely exemplary and that other process or deposition chambers may be used with the invention. Further details on exemplary deposition chambers that can be used with the invention can be found in U.S. patent application Ser. No. 11/965,689, now U.S. Pat. No. 8,039,052, entitled “Multi-region Processing System and Heads”, filed Dec. 27, 2007, and claiming priority to U.S. Provisional Application No. 60/970,500 filed on Sep. 6, 2007, and U.S. patent application Ser. No. 12/027,980, entitled “Combinatorial Process System”, filed Feb. 7, 2008 and claiming priority to U.S. Provisional Application No. 60/969,955 filed on Sep. 5, 2007, the entireties of which are hereby incorporated by reference.

The processing chamber 400 includes a bottom chamber portion 402 disposed under a top chamber portion 418. A substrate support 404 is provided within the bottom chamber portion 402. The substrate support 404 is configured to hold a substrate 406 disposed thereon and can be any known substrate support, including but not limited to a vacuum chuck, electrostatic chuck or other known mechanisms.

The substrate 406 may be a conventional 200 mm and 300 mm wafers, or any other larger or smaller size. In some embodiments, substrate 406 may be a square, rectangular, or other shaped substrate. The substrate 406 may be a blanket substrate, a coupon (e.g., partial wafer), or even a patterned substrate having predefined regions. In some embodiments, substrate 406 may have regions defined through site-isolated processing as described herein.

The top chamber portion 418 of the chamber 400 includes a process kit shield 412, which defines a confinement region over a portion of the substrate 406. As shown in FIG. 4, the process kit shield 412 includes a sleeve having a base (optionally integrated with the shield) and an optional top. It will be appreciated, however, that the process kit shield 412 may have other configurations. The process kit shield 412 is configured to confine plasma generated in the chamber 400 by sputter guns 416. The positively-charged ions in the plasma strike a target and dislodge atoms from the target. The sputtered neutrals are deposited on an exposed surface of substrate 406. In some embodiments, the process kit shield 412 may be partially moved in and out of chamber 400, and, in other embodiments, the process kit shield 412 remains in the chamber for both full substrate and combinatorial processing.

The base of process kit shield 412 includes an aperture 414 through which a surface of substrate 406 is exposed for deposition processing. The chamber may also include an aperture shutter 420 which is moveably disposed over the base of process kit shield 412. The aperture shutter 420 slides across a bottom surface of the base of process kit shield 412 in order to cover or expose aperture 414. In some embodiments, the aperture shutter 420 is controlled by an arm extension (not shown) which moves the aperture shutter to expose or cover aperture 414.

As shown in FIG. 4, the chamber 400 includes two sputter guns 416. While two sputter guns are illustrated, any number of sputter guns may be included, e.g., one, three, four or more sputter guns may be included. Where more than one sputter gun is included, the plurality of sputter guns may be referred to as a cluster of sputter guns. In addition, other sputter systems can be used, such as magnetron sputter systems.

The sputter guns 416 are moveable in a vertical direction so that one or both of the guns may be lifted from the slots of the shield. In some embodiments, sputter guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc. and the tilt angle may be varied.

The chamber may also include a gun shutter 422, which seals off the deposition gun when the process gun 416 is not needed during processing. The gun shutter 422 allows one or more of the sputter guns 416 to be isolated from certain processes as needed. It will be appreciated that the gun shutter 422 may be integrated with the top of the process kit shield 412 to cover the opening as the process gun 416 is lifted or individual gun shutter 422 can be used for each process gun 416.

The sputter guns 416 may be fixed to arm extensions 416a to vertically move sputter guns 416 toward or away from top chamber portion 418. The arm extensions 416a may be attached to a drive, e.g., lead screw, worm gear, etc. The arm extensions 416a may be pivotally affixed to sputter guns 416 to enable the sputter guns to tilt relative to a vertical axis. In some embodiments, sputter guns 416 tilt toward aperture 414 when performing combinatorial processing and tilt toward a periphery of the substrate being processed when performing full substrate processing. It will be appreciated that sputter guns 416 may alternatively tilt away from aperture 414.

The chamber 400 also includes power sources 424 and 426. Power source 424 provides power for sputter guns 416, and power source 426 provides RF power to bias the substrate support 404. In some embodiments, the output of the power source 426 is synchronized with the output of power source 424. The power source, 424, may output a direct current (DC) power supply, a direct current (DC) pulsed power supply, a radio frequency (RF) power supply or a DC-RF imposed power supply. The power sources 424 and 426 may be controlled by a controller (not shown) so that both deposition and etch can be performed in the chamber 400, as will be described in further detail hereinafter.

The chamber 400 may also include an auxiliary magnet 428 disposed around an external periphery of the chamber 400. The auxiliary magnet 428 is located between the bottom surface of sputter guns 416 and proximity of a substrate support 404. The auxiliary magnet may be positioned proximate to the substrate support 404, or, alternatively, integrated within the substrate support 404. The magnet 428 may be a permanent magnet or an electromagnet. In some embodiments, the auxiliary magnet 428 improves ion guidance as the magnetic field above substrate 406 is re-distributed or optimized to guide the metal ions. In some other embodiments, the auxiliary magnet 428 provides more uniform bombardment of ions and electrons to the substrate and improves the uniformity of the film being deposited.

The substrate support 404 is capable of both rotating around its own central axis 408 (referred to as “rotation” axis), and rotating around an exterior axis 410 (referred to as “revolution” axis). Such dual rotary substrate supports can be advantageous for combinatorial processing using site-isolated mechanisms. Other substrate supports, such as an XY table, can also be used for site-isolated deposition. In addition, substrate support 404 may move in a vertical direction. It will be appreciated that the rotation and movement in the vertical direction may be achieved through one or more known drive mechanisms, including, for example, magnetic drives, linear drives, worm screws, lead screws, differentially pumped rotary feeds, and the like.

Through the rotational movement of the process kit shield 412 and the corresponding aperture 414 in the base of the process kit shield, in combination with the rotational movement of substrate support 404, any region of a substrate 406 may be accessed for combinatorial processing. The dual rotary substrate support 404 allows any region (i.e., location or site) of the substrate 406 to be placed under the aperture 414; hence, site-isolated processing is possible at any location on the substrate 406. It will be appreciated that removal of the aperture 414 and aperture shutter 420 from the chamber 400 or away from the substrate 406 and enlarging the bottom opening of the process kit shield 412 allows for processing of the full substrate.

As described above, embodiments of the invention allow for both sputter deposition and plasma etch to be performed in the same process chamber (e.g., chamber 400). In some embodiments of the invention, the chamber 400 is configured so that both sputter deposition and plasma etch can be performed in the chamber 400, and, in particular, the chamber 400 is configured to allow for both site-isolated sputter deposition and plasma etch to be performed in the chamber. It will be appreciated that full wafer sputter deposition and plasma etch may also be performed in the chamber 400 by removing the aperture 414 away from the chamber 400 or moving the aperture 414 away from the substrate 406 and enlarging the bottom opening of the process kit shield 412.

In particular, plasma etch may be performed in the chamber 400 by applying RF power from the power source 426 to bias the substrate support (e.g., an electrostatic chuck) 404 with or without DC plasma near the sputter target. Plasma is then ignited on top of the substrate 406, which is confined by the aperture 414 and shield 412 above the substrate 406 so that site-isolated plasma etch of the substrate 406 can occur in the chamber 400. Sputter deposition may similarly be performed in the chamber 400 by applying DC power from the power source 424 to the sputter gun(s) 416. Three modes of processing can be performed in chamber 400: sputter deposition only, simultaneous sputter deposition and plasma etch, and plasma etch only.

In one embodiment, the RF power is any value or range of values between about 50 W and about 2000 W. In some embodiments, DC or pulsed DC power applied to sputter sources can have peak powers as high as 10 kW, for example, for high metal ionization in sputter deposition. The RF power frequency may be any value or range of values between about 40 kHz and about 60 MHz. It will be appreciated that the RF power frequency may be less than about 40 kHz or greater than about 60 MHz.

In chamber 400, plasma etch can be used to clean the substrate 406. An exemplary process according to some embodiments of the invention may begin by cleaning the substrate, performing site-isolated sputter deposition, performing site-isolated plasma etch, performing full substrate sputter deposition and then performing a subsequent full substrate plasma etch, all within the same chamber (e.g., chamber 400). Another exemplary process according to some embodiments of the invention may begin by cleaning the substrate, performing a full substrate sputter deposition, performing site-isolated sputter deposition, performing site-isolated plasma etch, performing full substrate sputter deposition, and performing a subsequent full substrate plasma etch, all within the same chamber (e.g., chamber 400). It will be appreciated that the above processes are merely exemplary and that processes according to the invention may include fewer steps or additional steps and that the order of the steps may vary.

In some embodiments, the present invention discloses methods and systems for plasma processing site isolated regions on a substrate, wherein the rest of the substrate is shielded from the plasma environment. In some embodiments, the present invention further discloses methods and systems for a shield assembly to prevent stray plasma on the unwanted portion of the substrate, e.g., the substrate area outside the site isolated regions that is not intended to be processed.

FIG. 5A is a simplified schematic diagram illustrating a cross-section of the substrate support and aperture. The hardware is also described in U.S. patent application Ser. No. 13/316,882 entitled “Combinatorial RF Bias Method For PVD” filed on Dec. 12, 2011 which is herein incorporated by reference. Similar to FIG. 4, the base of the process kit shield comprises an aperture, 514. The process kit shield is typically formed from a conductive material. A substrate, 506, is supported on the substrate support, 504. A power supply (not shown), is connected to an electrode (not shown) through a matching network (not shown), incorporated into the substrate support and is used to apply a bias voltage to the substrate support and/or the substrate. In some embodiments, the bias voltage is an RF bias voltage and the frequency of the RF bias voltage may vary between about 300 k Hz and about 60 MHz. Typically, the application of RF bias voltage to a substrate was developed for use in conventional plasma processing chambers. In conventional plasma processing chambers, there is not a shield held at ground potential disposed close to the substrate surface as illustrated in FIG. 5. However, for combinatorial processing, the base of the process kit shield, comprising aperture, 514, is required to define the site-isolated regions on the substrate surface. The goal is to restrict the effects of the RF bias only to the site-isolated region below the aperture. The presence of the base of the process kit shield close to the substrate surface gives two paths for the applied RF bias power to go to ground, as illustrated in FIG. 5B. The first path (i.e. “1”) would be the typical path where the applied RF bias power couples to the plasma generated within the process chamber. The second path (i.e. “2”) would be through a plasma generated between the substrate surface and the base of the process kit shield. In practice, path “2” represents the lowest impedance path to ground and most of the power would be coupled to ground through path “2”.

Those skilled in the art will understand that a plasma formed between the substrate surface and the base of the process kit shield would be undesirable. Firstly, much of the RF power applied to the substrate would be directed away from the site-isolated region under the aperture, 514, and the benefits of the RF bias voltage would not be realized. Secondly, the plasma formed between the substrate surface and the base of the process kit shield would damage regions of the substrate that were not intended to be processed (i.e. those regions not under the aperture).

In some embodiments, the present invention discloses methods and systems to eliminate the plasma formation between the substrate and the process shield. Surrounding the plasma is a sheath region (e.g., dark space), for example, a sheath region near the substrate surface and another sheath region near the shield area. In some embodiments, the present invention discloses minimizing the gap between the shield and the substrate to prevent the formation of a plasma, for example, by restricting the distance between the shield and the substrate to be less than the width of the sheath regions. The space can be restricted by placing a conductive shield within a short distance (i.e. a gap) from the substrate, such as less than about 3 mm. The separation between the shield and the substrate is preferably uniform, for example, to prevent any concentration of electric field. Alternatively, the space can be restrictive by placing a ceramic material between the shield and the substrate.

In some embodiments, a conductive shield can be used to restrict the space between the shield and the substrate. FIGS. 5-7B illustrate additional features of the process chamber 400 according to some embodiments of the invention. The features shown in FIGS. 5-7B allow both physical vapor sputter deposition and plasma processing to be performed in the same chamber, eliminating the need for a separate plasma etch chamber.

FIG. 6A is a simplified schematic diagram illustrating a cross-section of the substrate support and aperture. The process shield kit has been separated into an upper part, 612, and a base, 636. The base of the process kit shield, 636, comprises an aperture, 614. The process kit shield is typically formed from a conductive material. The base of the process kit shield, 636, further comprises a ceramic insulation material, 634, disposed between the base of the process kit shield, 636, and the substrate surface. The ceramic insulation material fills the space between the base of the process kit shield, 636, and the substrate surface. The resulting gap can be maintained to less than about 2 mm and advantageously less than about 1 mm. A low-pass filter, 632, has been inserted between the base of the process kit shield, 636, and ground. The low-pass filter is operable to block high frequency power from passing through to ground, but will allow low frequency power or DC power to pass through to the ground. The low-pass filter also prevents the base of the process kit shield, 636, from accumulating a charge. Those skilled in the art will understand that the frequency cut-off for the low-pass filter can be selected through the choice of the values of the inductor, resistor, and capacitor used to form the circuit. The base of the process kit shield, 636, can also be connected to the upper shield which is held at ground potential, however, the low-pass filter is advantageous. A substrate, 606, is supported on the substrate support, 604. A power supply, 626, is connected to an electrode, 630 through a matching network (not shown), incorporated into the substrate support and is used to apply RF bias voltage to the substrate support and/or substrate. The frequency of the RF bias voltage may vary between about 300 k Hz and about 60 MHz. An equivalent electrical circuit is illustrated in FIG. 6B wherein the substrate support and substrate, the shield with the ceramic, and the plasma are all represented by simple resistor-capacitor (RC) circuit elements. Typically, the application of RF bias voltage to a substrate was developed for use in conventional plasma processing chambers. In these chambers, there is not a shield held at ground potential disposed close to the substrate surface as illustrated in FIG. 6A. However, for combinatorial processing, the base of the process kit shield, 612, comprising aperture, 614, is required to generate the isolated sites on the substrate surface. The goal is to restrict the effects of the RF bias only to the site isolated region below the aperture. The implementation of the base of the process kit shield, 636, with the ceramic insulation material, and the low-pass filter connected to the base leaves only a single path for the applied RF power to go to ground. The path would be the typical path where the applied RF power couples to the plasma generated within the process chamber. This is illustrated as path “1” in FIGS. 6A and 6B. The implementation of the base of the process kit shield, 636, with the ceramic insulation material, and the low-pass filter connected to the base has been described with relation to a PVD application, however, those skilled in the art will understand that this configuration is also applicable to plasma-etch, plasma enhanced chemical vapor deposition (PECVD), plasma enhanced atomic layer deposition (PEALD), or plasma surface treatment applications configured for high productivity combinatorial deposition. The use of PVD as an example does not limit the scope of the present invention.

FIG. 7 is a partial cross-sectional view of the process chamber showing a lower portion of chamber. The lower chamber includes a lower shield (i.e., a lower portion of shield 412). The lower chamber also includes an aperture disc 704, which includes the aperture 714, and aperture plate 736. The substrate 706 is positioned on the substrate support 704 under the aperture disc 704 and aperture plate 736.

A dark space gap 708 is formed between the substrate 706 and the aperture disc 704, and between the substrate 706 and the aperture plate 736. The dark-space gap 708 prevents plasma leaking from the enclosure formed by the chamber shield kit 702, aperture plate 736, and aperture disc 704. In some embodiments of the present invention, the dark-space gap 708 is any value or range of values between about 0 mm and about 3 mm and, in some embodiments, the dark space gap 708 may be between about 1 mm and about 3 mm. It will also be appreciated that the dark-space gap 708 may be greater than 3 mm. In some embodiments, uniformity of the dark space gap 708 thickness is within about 0.5 mm. It will be appreciated that the gap uniformity may be less than or greater than about 0.5 mm.

The lower chamber also includes a deposition ring 710, a weight ring 712, a wing plate 714 and a wing plate holder 716. When a substrate such as a wafer is processed combinatorially with its center aligned with the center of the chamber, plasma confinement is satisfied with shield 702, aperture disc 704, aperture plate 736, deposition ring 710 and weight ring 712. However, when the substrate is moved to an off-center location for spot-isolated deposition or etch and a part of the substrate 706 and substrate support 704 is now outside the shield 702 and becomes exposed, wing plate 714 is needed to shield the exposed substrate and prevent stray plasma from being ignited due to the RF power applied to substrate support 704. The wing plate 714 is coupled to the wing plate holder 716, which is coupled to the chamber enclosure. The wing plate 714 is configured such that it is flush at the bottom with the aperture plate 736. Since wing plate 714 is stationery while the substrate and deposition ring can move with a dual-axis rotation mechanism or X-Y table, wing plate 714 is as large as the design envelope.

Because the weight ring is a ceramic material and the bottom of the aperture is flush with the bottom of the lower shield, a small, constant, dark-space gap is ensured between the grounded shield and the entire substrate (except a spot exposed by the aperture hole). A chamber with one or multiple sputter guns can be used for both plasma processing and sputter deposition. Plasma processing can be performed by applying power (e.g. RF, DC, pulsed, or the like) from a power source to the substrate support and igniting plasma with gas flow, whereas sputter deposition can be carried out by applying power (e.g. DC, RF, and the like) from the power source to the sputter gun(s) and igniting plasma with gas flow to sputter the target. In alternative embodiments, oxygen or nitrogen gases can be flowed into the chamber to perform reactive sputter deposition or the plasma etch.

It will be appreciated that the chamber may have different configurations. For example, in some embodiments, instead of using the deposition ring 710 and weight ring 712 to control the dark-space gap 708, the dark-space gap 708 may be filled with a dielectric material to prevent plasma leak.

In some embodiments, it may be desirable to expose the entire surface of the substrate to the plasma etch or plasma surface treatment. The plasma etch or plasma surface treatment may be performed before the PVD deposition, after the PVD deposition, or both before and after the PVD deposition. In these embodiments, the lower shield with the aperture may be removed from the space between the PVD target and the substrate. The shield may be removed and stored in-situ, without having to open the process chamber and expose the substrate to the ambient. Alternatively, the size of the aperture may be adjustable and the size of the aperture can be increased so that the entire surface of the substrate can be exposed to the plasma etch or plasma surface treatment. As before, the size of the aperture can be adjusted without having to open the process chamber and expose the substrate to the ambient.

During “reactive sputtering” wherein a reactive gases (e.g. oxygen, nitrogen, and the like) are introduced into the sputtering atmosphere, it is known that the target surface becomes converted to a metal compound (e.g. an oxide, a nitride, or the like). This is especially true in the mode known as “poisoned mode” wherein the surface of the target is completely converted. Generally, the deposition rate decreases since the sputtering yield of the metal compounds is smaller than the pure metal. The conversion of the target surface is facilitated by the negative bias on the target and the excitation of the reactive gases.

This configuration can be reversed to cause the same conversion of the substrate surface. In some embodiments, a negative bias is applied to the substrate holder (and therefore, the substrate). The bias may be applied as RF, DC, pulsed, or the like. Generally, the bias voltage is applied in the range between about 50V and about 300V. The biased substrate may be exposed to a plasma including a reactive species (e.g. oxygen, nitrogen, and the like) and the surface will be subjected to a plasma process (e.g. etching, nitridation, oxidation, and the like).

In some embodiments, the shielding and hardware discussed previously with reference to FIGS. 5-7 can be used to apply the plasma process to site-isolated regions on the substrate surface where one or more process parameters can be varied in a combinatorial manner between the site-isolated regions. Low power may be applied to the sputter guns to maintain the plasma. Power levels as low as 25 W to 50 W can be used to sustain the plasma. At these power levels, the deposition from the targets will be minimal.

In some embodiments, the entire surface of the substrate is exposed and the plasma processing (e.g. etching, nitridation, oxidation, and the like) can be applied uniformly to the entire surface of the substrate. In this configuration, the shielding and hardware discussed previously with reference to FIGS. 5-7 can be removed or transferred to a different location so that the entire surface of the substrate is exposed.

The results of the plasma processing can be influenced by controlling one or more processing parameters such as gas flow ratio, gas flow composition (e.g. the concentration of reactive species such as O₂, N₂, F-sources, CI-sources, H₂, etc.), substrate bias power, substrate bias frequency, processing time, substrate temperature, and the like. These processing parameters can be varied in a combinatorial manner across the various site-isolated regions on the surface of the substrate. By controlling one or more of these processing parameters, results such as etch rate and/or etch selectivity can be evaluated across the various site-isolated regions on the surface of the substrate if the plasma process is a plasma etch process. By controlling one or more of these processing parameters, results such as layer stoichiometry and/or surface treatment depth can be evaluated across the various site-isolated regions on the surface of the substrate if the plasma process is a plasma surface treatment process.

FIG. 8 illustrates an exemplary flowchart for processing a substrate according to some embodiments. Operation 800 positions a substrate on a substrate support. The substrate support is preferably disposed in a vacuum process chamber. The substrate support can be an electrostatic chuck (ESC) or other suitable substrate holder configuration. The substrate support preferably comprises a conductive material for acting as an electrode for a bias voltage source. Operation 810 applies a bias voltage to the substrate support to form a plasma. In some embodiments, the bias voltage is applied using RF power. The plasma is generated above the substrate and can assist in processing the substrate surface. For example, by applying about 100 W RF power to the substrate support, a DC bias voltage of about −100V can occur at the substrate surface, and the substrate can be plasma processed (e.g. plasma etch or plasma surface treatment).

Operation 820 places a shield on the substrate, wherein the shield comprises an aperture for exposing a site isolated region of the substrate. The shield covers the substrate surface, exposing only the site-isolated region of the substrate to the plasma. Thus the shield can enable site-isolated plasma processing, (e.g. etching, plasma surface treatment) the exposed site-isolated region. The aperture is operable for enabling sputter deposition or plasma processing of an isolated site on the substrate.

The shield can physically block the ion bombardment, preventing the shielded portion of the substrate surface from being plasma processed. In some embodiments, the shield forms a gap with the substrate, wherein the gap has a width smaller than that of a sheath of the plasma. Thus, the plasma generated by the bias voltage is confined to the region above the substrate and the shield, without any plasma generated in the gap formed between the shield and the substrate. Thus there is no plasma on the covered portion of the substrate, allowing the bias voltage to be fully applied to the exposed site isolated region, and further preventing the covered surface region from being processed.

In some embodiments, the width of the gap is less than about 3 mm. The width of the plasma sheath depends on the operating conditions, such as the bias voltage and the ambient species, but in general, for semiconductor process conditions, a gap less than about 3 mm can be used for minimizing stray plasma formation. Thinner gap can also be used, for example, about 2 mm or about 2.5 mm. In some embodiments, zero gaps can be used, for example, by contacting the shield with the substrate surface. In general, the width of the gap is preferably greater than about 1 mm.

In some embodiments, the shield can comprise a conductive material, such as a metal. The shield can also comprise an insulating material, such as a ceramic material. In some embodiments, the shield is electrically connected to ground. Alternatively, the shield can be electrically connected to the ground through a low pass filter. The low pass filter can prevent high frequency plasma from re-directing to the shield area, thus the plasma can be focused on the site-isolated regions to be processed. In some embodiments, one or more sputter guns can be used in the process chamber, for example, to sputter deposit a layer of material on the site-isolated regions, either before or after the plasma processing.

In some embodiments, a combination of plasma processing and plasma deposition, which are performed in the same process chamber is disclosed. A bias voltage can be applied to a substrate support to generate a plasma for plasma processing a substrate surface. A sputter gun can be disposed above the substrate for sputter depositing a layer of material on the substrate surface, either before or after the plasma processing. In addition, a shield can be disposed on the substrate surface to cover the substrate, exposing only one or more site-isolated regions for processing.

FIG. 9 illustrates an exemplary flowchart for processing a substrate according to some embodiments. In some embodiments, the surface of the substrate (e.g. the surface of a site-isolated region) is exposed to a plasma process before the subsequent deposition of a layer. The plasma processing and the PVD deposition can be performed in the same chamber, in-situ. Operation 900 positions a substrate on a substrate support. Operation 910 shields the substrate surface while exposing at least one site-isolated region of the substrate, wherein the shield forms a gap with the substrate, wherein the gap has a width smaller than 3 mm. Operation 920 plasma processes the exposed site isolated region, wherein the plasma processing comprises applying a bias voltage to the substrate support. The bias voltage may be applied using RF, DC, or pulsed power. Operation 930 deposits a layer of material on the exposed site-isolated region, wherein the deposition comprises using a sputter gun.

FIG. 10 illustrates an exemplary flowchart for processing a substrate according to some embodiments. In some embodiments, a layer is deposited on the surface of the substrate (e.g. the surface of a site-isolated region) before being exposed to a subsequent plasma process. The PVD deposition and the plasma processing can be performed in the same chamber, in-situ. Operation 1000 positions a substrate on a substrate support. Operation 1010 shields the substrate surface while exposing at least one site-isolated region of the substrate, wherein the shield forms a gap with the substrate, wherein the gap has a width smaller than 3 mm. Operation 1020 deposits a layer of material on the exposed site-isolated region, wherein the deposition comprises using a sputter gun. Operation 1030 plasma processes the exposed site isolated region, wherein the plasma processing comprises applying a bias voltage to the substrate support. The bias voltage may be applied using RF, DC, or pulsed power.

FIG. 11 illustrates an exemplary flowchart for processing a substrate according to some embodiments. In some embodiments, the surface of the substrate (e.g. the surface of a site-isolated region) is exposed to a first plasma process before the subsequent deposition of a layer. After the deposition of the layer, the surface of the substrate is exposed to a second plasma process. The first plasma process and the second plasma process may be the same or may be different. The plasma processing and the PVD deposition can be performed in the same chamber, in-situ. Operation 1100 positions a substrate on a substrate support. Operation 1110 shields the substrate surface while exposing at least one site-isolated region of the substrate, wherein the shield forms a gap with the substrate, wherein the gap has a width smaller than 3 mm. Operation 1120 plasma processes the exposed site isolated region using a first plasma process, wherein the first plasma process comprises applying a bias voltage to the substrate support. The bias voltage may be applied using RF, DC, or pulsed power. Operation 1130 deposits a layer of material on the exposed site-isolated region, wherein the deposition comprises using a sputter gun. Operation 1140 plasma processes the exposed site isolated region using a second plasma process, wherein the second plasma process comprises applying a bias voltage to the substrate support. The bias voltage may be applied using RF, DC, or pulsed power.

FIG. 12 illustrates an exemplary flowchart for processing a substrate according to some embodiments. In some embodiments, a first material is deposited on the surface of the substrate (e.g. the surface of a site-isolated region) before being exposed to a plasma process. After the plasma processing of the layer, a second material is deposited on the surface of the substrate. The first material and the second material may be the same or may be different. The PVD deposition and the plasma processing can be performed in the same chamber, in-situ. Operation 1200 positions a substrate on a substrate support. Operation 1210 shields the substrate surface while exposing at least one site-isolated region of the substrate, wherein the shield forms a gap with the substrate, wherein the gap has a width smaller than 3 mm. Operation 1220 deposits a layer of a first material on the exposed site-isolated region, wherein the deposition comprises using a sputter gun. Operation 1230 plasma processes the exposed site isolated region, wherein the plasma processing comprises applying a bias voltage to the substrate support. The bias voltage may be applied using RF, DC, or pulsed power. Operation 1240 deposits a layer of a second material on the exposed site-isolated region, wherein the deposition comprises using a sputter gun.

In some embodiments, the present invention discloses a method for combinatorially processing a substrate. An exemplary method is characterized in that: site-isolated sputter deposition and site-isolated plasma processing are performed in the same process chamber. The method can further comprise positioning a substrate on a substrate support; and shielding the substrate surface while exposing at least one site-isolated region of the substrate, wherein the shield forms a gap with the substrate, wherein the gap has a width smaller than 3 mm.

Processes for controlling, for example, whether sputter deposition, plasma processing or both is performed in the deposition chamber may be embodied in a computer-readable medium on which is stored one or more sets of instructions (e.g., software). The software may reside, completely or at least partially, within memory and/or within a processor of the controller during execution thereof. The term “computer-readable medium” should be taken to include a single medium or multiple media that store the one or more sets of instructions. The term “computer-readable medium” shall also be taken to include any medium that is capable of storing, encoding or carrying a set of instructions for execution by a machine and that cause a machine to perform any one or more of the methodologies of the present invention. The term “computer-readable medium” shall accordingly be taken to include, but not be limited to, solid-state memories, and optical and magnetic media.

The invention has been described in relation to particular examples, which are intended in all respects to be illustrative rather than restrictive. Various aspects and/or components of the described embodiments may be used singly or in any combination. It is intended that the specification and examples be considered as exemplary only, with a true scope and spirit of the invention being indicated by the claims.

What is claimed is:

1. A method for processing a substrate, comprising:
positioning a substrate on a substrate support in a process chamber;
placing a shield above the substrate, wherein the shield comprises an aperture for defining a site-isolated region on a surface of the substrate;
applying a bias voltage to the substrate support, thereby forming a plasma above the substrate;
performing a plasma process on the site-isolated region on the surface of the substrate; and
depositing a layer of material on the site-isolated region on the surface of the substrate without removing the substrate from the process chamber.

2. The method of claim 1 wherein the bias voltage is applied using RF power.

3. The method of claim 1 wherein the plasma process is one of plasma etch or plasma surface treatment.

4. The method of claim 3 wherein the plasma surface treatment is one of nitridation, oxidation, fluorination, chlorination, or hydrogen treatment.

5. The method of claim 1 wherein the depositing a layer of material on the site-isolated region uses a PVD technique.

6. A method for processing a substrate, comprising:
positioning a substrate on a substrate support in a process chamber;
placing a shield above the substrate, wherein the shield comprises an aperture for defining a site-isolated region on a surface of the substrate;
depositing a layer of material on the site-isolated region on the surface of the substrate;
applying a bias voltage to the substrate support after the depositing, thereby forming a plasma above the substrate; and
performing a plasma process on the site-isolated region on the surface of the substrate without removing the substrate from the process chamber.

7. The method of claim 6 wherein the bias voltage is applied using RF power.

8. The method of claim 6 wherein the plasma process is one of plasma etch or plasma surface treatment.

9. The method of claim 8 wherein the plasma surface treatment is one of nitridation, oxidation, fluorination, chlorination, or hydrogen treatment.

10. The method of claim 6 wherein the depositing a layer of material on the site-isolated region uses a PVD technique.

11. A method for processing a substrate, comprising:
positioning a substrate on a substrate support in a process chamber;
placing a shield above the substrate, wherein the shield comprises an aperture for defining a site-isolated region on a surface of the substrate;
applying a bias voltage to the substrate support, thereby forming a plasma above the substrate;
performing a first plasma process on the site-isolated region on the surface of the substrate;
depositing a layer of material on the site-isolated region on the surface of the substrate after the first plasma process without removing the substrate from the process chamber; and
performing a second plasma process on the site-isolated region on the surface of the substrate after the depositing without removing the substrate from the process chamber.

12. The method of claim 11 wherein the bias voltage is applied using RF power.

13. The method of claim 11 wherein the first plasma process is one of plasma etch or plasma surface treatment.

14. The method of claim 13 wherein the first plasma surface treatment is one of nitridation, oxidation, fluorination, chlorination, or hydrogen treatment.

15. The method of claim 11 wherein the second plasma process is one of plasma etch or plasma surface treatment.

16. The method of claim 15 wherein the second plasma surface treatment is one of nitridation, oxidation, fluorination, chlorination, or hydrogen treatment.

17. The method of claim 11 wherein the depositing a layer of material on the exposed site-isolated region uses a PVD technique.

18. A method for processing a substrate, comprising:
positioning a substrate on a substrate support in a process chamber;
placing a shield above the substrate, wherein the shield comprises an aperture for defining a site-isolated region on a surface of the substrate;
depositing a layer of a first material on the site-isolated region on the surface of the substrate;
applying a bias voltage to the substrate support after the depositing, thereby forming a plasma above the substrate;
performing a plasma process on the site-isolated region on the surface of the substrate without removing the substrate from the process chamber; and
depositing a layer of a second material on the site-isolated region on the surface of the substrate after the plasma process without removing the substrate from the process chamber.

19. The method of claim 18 wherein the bias voltage is applied using RF power.

20. The method of claim 6 wherein the plasma process is a plasma surface treatment and is one of nitridation, oxidation, fluorination, chlorination, or hydrogen treatment.
